(19) United States
(12) Patent Application Publication
(10) Pub. No.: US 2016/0148801 A1
(43) Pub. Date: May 26, 2016

(54) SUBSTRATE PROCESSING APPARATUS, SUBSTRATE PROCESSING METHOD AND STORAGE MEDIUM

(71) Applicant: TOKYO ELECTRON LIMITED, Tokyo (JP)

(72) Inventors: Kazuo YABE, Nirasaki City (JP); Akira SHIMIZU, Nirasaki City (JP); Kazuhide HASEBE, Nirasaki City (JP)

(21) Appl. No.: 14/940,843

(22) Filed: Nov. 13, 2015

(30) Foreign Application Priority Data
Nov. 25, 2014 (JP) 2014-238004

(51) Int. Cl. H01L 21/02; C23C 16/455

(52) U.S. Cl. CPC H01L 21/0228; C23C 16/45544

(57) ABSTRACT

A substrate processing apparatus, that performs oxidization on a surface of a substrate in a vacuum atmosphere formed in a vacuum chamber, includes an atmosphere gas supply part configured to supply an atmosphere gas into the vacuum chamber to form a processing atmosphere containing ozone and hydrogen donor, wherein a concentration of the ozone is above a threshold concentration to trigger chain reaction of decomposition. The substrate processing apparatus further includes an energy supply part configured to supply an energy to the processing atmosphere to oxidize a surface of a substrate with reactive species generated by forcibly decomposing the ozone and hydroxyl radical generated by reaction of the hydrogen donor.

### CROSS-REFERENCE TO RELATED APPLICATION

This application claims the benefit of Japanese Patent Application No. 2014-238004, filed on Nov. 25, 2014 in the Japan Patent Office, the disclosure of which is incorporated herein in its entirety by reference.

### TECHNICAL FIELD

The present disclosure relates to a substrate processing apparatus for oxidizing a surface of a substrate in a vacuum atmosphere, a substrate processing method, and a non-transitory computer-readable storage medium.

### BACKGROUND

Manufacturing processes of semiconductor devices often involve a process of oxidizing a surface of a semiconductor wafer (hereinafter referred to as a “wafer”) which is a substrate. Such a process of oxidizing is known in the art. As an example of such a process of oxidizing, the atomic layer deposition (ALD) technique is known, by which a thin film such as silicon dioxide SiO₂ is formed on a surface of a wafer.

In such a process of oxidizing, a number of methods are used including; a method in which an oxidizing gas such as oxygen or ozone is supplied onto a wafer; a method called “low pressure radical oxidation (LPRO)” in which hydrogen and oxygen are supplied onto a wafer to generate oxygen radical at a relatively low pressure; a method in which plasma generated by oxygen is used in a vacuum chamber; or a method called “in-situ steam generation (ISSG)” in which steam generated from hydrogen gas and oxygen gas is used. However, performing oxidation by supplying oxygen gas requires heating a wafer with a relatively high temperature in order to make the oxygen gas chemically react with the source. Even with the LPRO and the ISSG, a wafer has to be heated to, for example, 400 degrees C. or higher and 900 degrees C. or higher, respectively.

Therefore, heating equipment such as a heater is installed in the apparatus, and thus manufacturing or maintenance cost increases. In addition, oxidation of the source cannot be performed until a wafer loaded into the apparatus is heated to a predetermined temperature, and thus it is difficult to reduce the processing time. When the oxygen plasma is used, although the components of source gas deposited on a wafer can be oxidized even at room temperature, due to the reactive plasma species consisting of ions and electrons having linearity, the film quality of top portions of a pattern of the wafer becomes different from that of side portions, and eventually the film quality of the side portions becomes worse than that of the top portions. For this reason, oxidation with plasma cannot be used for forming fine patterns.

In addition, there is a known technique in which ozone is decomposed by chain reaction to produce reactive oxygen species, and oxidation is carried out at the room temperature by the reactive oxygen species. However, the reactive oxygen species are unstable and lose reactivity in an extremely short period of time. Accordingly, the chain reaction of decomposition has to be repeated a number of times in order to perform oxidation of a source sufficiently on a surface of a wafer, and thus the throughput cannot be increased. Moreover, there is an attempt to manufacture a semiconductor device having a channel formed of germanium (Ge) or a channel formed of elements in Group 3 of the periodic table such as gallium and elements in Group 5 of the periodic table. In the processes of manufacturing such a semiconductor device, it is required to suppress the temperature of a wafer below 350 degrees C.

Under the circumstances, the present disclosure is directed to provide a technique that carries out oxidation on a surface of a substrate sufficiently without employing any heating equipment for heating the substrate.

### SUMMARY

According to one embodiment of the present disclosure, a substrate processing apparatus for oxidizing a surface of a substrate in a vacuum atmosphere formed within a vacuum chamber includes: an atmosphere gas supply part configured to supply an atmosphere gas into the vacuum chamber to form a processing atmosphere containing an ozone and a hydrogen donor, wherein a concentration of the ozone is above a threshold concentration to trigger chain reaction of decomposition; and an energy supply part configured to supply an energy to the processing atmosphere to oxidize the surface of the substrate with reactive species generated by forcibly decomposing the ozone and a hydroxyl radical generated by reaction of the hydrogen donor.

According to another embodiment of the present disclosure, there is provided a substrate processing method of oxidizing a surface of a substrate in a vacuum atmosphere formed within a vacuum chamber, the method including: supplying an atmosphere gas into the vacuum chamber to form a processing atmosphere containing an ozone and a hydrogen donor, wherein a concentration of the ozone is above a threshold concentration to trigger chain reaction of decomposition; and supplying an energy to the processing atmosphere to oxide the surface of the substrate with reactive species generated by forcibly decomposing the ozone and hydroxyl radical generated by reaction of the hydrogen donor.

According to another embodiment of the present disclosure, there is provided a non-transitory computer-readable storage medium having a computer program thereon, wherein the computer program, when executed in a substrate processing apparatus for oxidizing a surface of a substrate in a vacuum atmosphere formed within a vacuum chamber, causes the apparatus to perform the substrate processing method as recited above.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal cross-sectional view of a film forming apparatus according to a first exemplary embodiment of the present disclosure.

FIG. 2 is a lateral cross-sectional view of the film forming apparatus.

FIG. 3 is a view illustrating a film forming process performed by the film forming apparatus.

FIG. 4 is a view illustrating a film forming process performed by the film forming apparatus.

FIG. 5 is a view illustrating a film forming process performed by the film forming apparatus.

FIG. 6 is a view illustrating a film forming process performed by the film forming apparatus.

FIG. 7 is a view illustrating a film forming process performed by the film forming apparatus.

FIG. 8 is a view illustrating a film forming process performed by the film forming apparatus.

FIG. 9 is a view illustrating a film forming process performed by the film forming apparatus.

FIG. 10 is a view schematically showing a wafer being subjected to the film forming process.

FIG. 11 is a view schematically showing a wafer being subjected to the film forming process.

FIG. 12 is a view schematically showing a wafer being subjected to the film forming process.

FIG. 13 is a view schematically showing a wafer being subjected to the film forming process.

FIG. 14 is a view schematically showing a wafer being subjected to the film forming process.

FIG. 15 is a view schematically showing a wafer being subjected to the film forming process.

FIG. 16 is a view schematically showing a wafer being subjected to the film forming process.

FIG. 17 is a longitudinal cross-sectional view of a film forming apparatus according to a second exemplary embodiment of the present disclosure.

FIG. 18 is a view illustrating a film forming process performed by the film forming apparatus.

FIG. 19 is a view illustrating a film forming process performed by the film forming apparatus.

FIG. 20 is a view illustrating a film forming process performed by the film forming apparatus.

FIG. 21 is a graph showing a result of Evaluation Test 1.

FIG. 22 is a graph showing a result of Evaluation Test 2.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

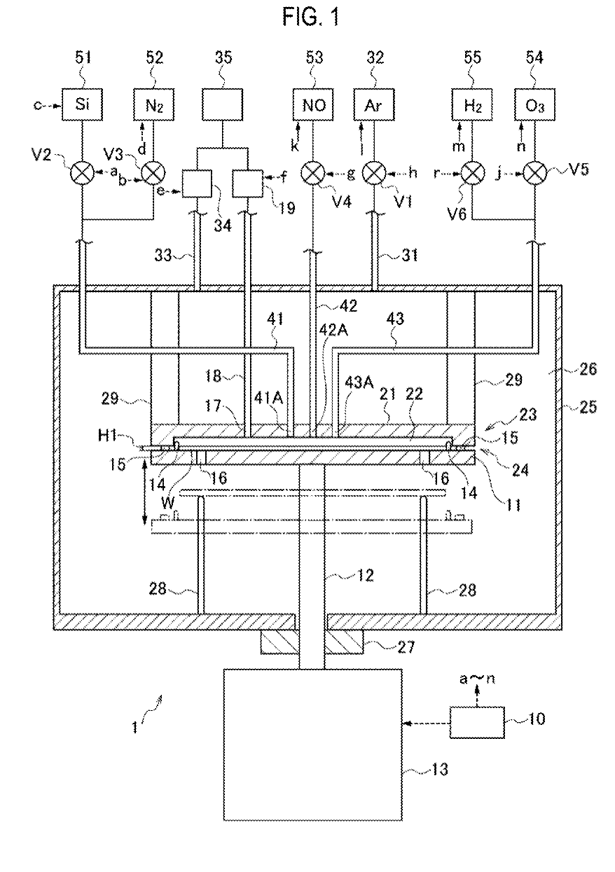

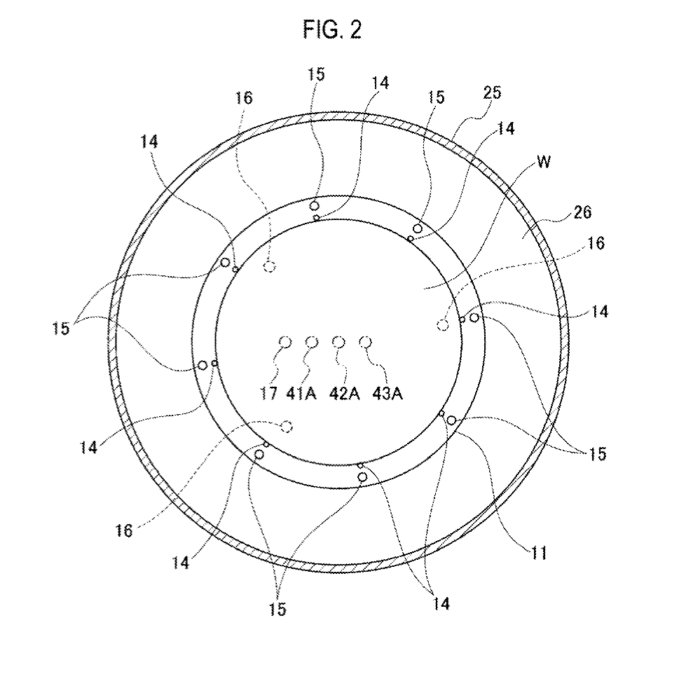

A film forming apparatus 1 according to a first exemplary embodiment of the present disclosure will be described with reference to the longitudinal cross-sectional view of FIG. 1 and the lateral cross-sectional view of FIG. 2. The film forming apparatus 1 forms a silicon dioxide film on a wafer W or a substrate by the ALD technique. In FIGS. 1 and 2, a circular stage 11 is disposed horizontally, on a surface of which a wafer W is loaded horizontally. A shaft 12 extending vertically is installed under the stage 11. A lower end of the shaft 12 is connected to an elevation mechanism 13, and the stage 11 may ascend and descend vertically by the elevation mechanism 13. In FIG. 1, the stage 11 is indicated by a solid line when it is in the upper position for performing a film forming process, and is indicated by a dash-dot line when it is in the lower position for passing/receiving the wafer W to/from a transfer mechanism (not shown).

Guide pins 14 for fixing the location of the wafer W to the surface of the stage 11 protrude upwardly from the surface of the stage 11. A plurality of the guide pins 14 are arranged in the circumferential direction of the stage 11 with spacing therebetween. The wafer W is loaded inside an area surrounded by the guide pins 14. In addition, spacing pins 15 are disposed on the surface of the stage 11 closer to the outer periphery than the guide pins 14. A plurality of the spacing pins 15 are also arranged in the circumferential direction of the stage 11 with spacing therebetween. The functionality of the spacing pins 15 will be described below. Three penetrating holes 16 are formed by punching the stage 11 in the thickness direction. The penetrating holes 16 are disposed closer to the center of the stage 11 than the guide pins 14. When a wafer W is loaded on the stage 11, the penetrating holes 16 are blocked by the wafer W.

A flat, circular hood 21 is disposed horizontally above the stage 11. The hood 21 has a recess in its lower surface. When the stage 11 having a wafer W loaded thereon is in the upper position, a processing space 22 surrounding the wafer W is defined by inner walls of the recess and the surface of the stage 11. The processing space 22 is evacuated during the processing of the wafer W and is turned into a vacuum atmosphere. The stage 11 and the hood 21 form the inner chamber 23 which is a vacuum container. The processing space 22 is neither heated nor cooled by the outside, and thus, is at room temperature. Each reaction to be described takes place at room temperature.

The lower portion of the hood 21 comes in contact with the upper ends of the spacing pins 15 to form the processing space 22, such that the lower portion of the hood 21 is raised over the surface of the stage 11. Accordingly, a gap 24 is created between the lower portion of the hood 21 and the surface of the stage 11. An external space (a buffer area 26 to be described below) of the inner chamber 23 is in communication with the processing space 22 via the gap 24. The height H1 of the spacing pins 15 is relatively small in order to suppress ozone gas from leaking from the processing space 22 when the ozone gas is supplied to the processing space 22, as will be described below. For example, the height H1 is 0.1 mm or less.

An outer chamber 25 surrounding the inner chamber 23 is installed in the film forming apparatus 1. The inner space of the outer chamber 25, i.e., the outer space of the inner chamber 23 is the buffer area 26. The buffer area is also evacuated during the processing of the wafer W and is turned into a vacuum atmosphere. When the pressure in the processing space 22 increases due to a chain reaction of decomposition to be described below, gas in the processing space 22 flows to the buffer area 26 via the gap 24 such that an increase in the pressure in the processing space 22 is mitigated. The pressure in the processing space 22 increases drastically due to the reaction of decomposition by twenty to thirty times greater than the pressure before the reaction of decomposition. Therefore, the volume of the buffer area 26 is designed to have the volume of, e.g., twenty times or more greater than the volume of the processing space 22 in order for the processing space 22 and the buffer area 26 to be maintained in the vacuum atmosphere.

The lower end of the shaft 12 penetrates through the bottom of the outer chamber 25 and is connected to the elevation mechanism 13 located outside the outer chamber 25. In addition, a sealing member 27 for sealing the space between the outer chamber 25 and the shaft 12 is installed. In addition, three supporting pins 28 for supporting the wafer W to face upward are disposed on the bottom of the outer chamber 25 at locations corresponding to the locations of the penetrating holes 16 formed in the stage 11. A transfer slot (not shown) that can be opened and closed is formed in the outer chamber 25. The wafer W is delivered between the outside the outer chamber 25 and the supporting pins 28 by the transfer mechanism via the transfer slot. In addition, when the stage 11 rises, the wafer W is delivered between the supporting pins 28 and the surface of the stage 11. In FIG. 1, the wafer W delivered to the supporting pins 28 is indicated by a dash-dot line.

As shown in FIG. 1, hanging members 29 hang the hood 21 from the ceiling of the buffer area 26. In addition, an end of a gas supply pipe 31 is opened in the buffer area 26. The other end of the gas supply pipe 31 is connected to an argon (Ar) gas supply source 32, which is an inert gas, via a valve V1 located outside the outer chamber 25. In addition, an end of an exhaust pipe 33 is opened in the buffer area 26. The other end of the exhaust pipe 33 is connected to an exhaust mechanism 35 such as a vacuum pump via a flow rate controller 34. The flow rate controller 34 may include, for example, a valve. The flow rate controller 34 adjusts the flow rate of gas flowing from the exhaust pipe 33 so that the buffer area 26 in the vacuum atmosphere is at a desired pressure.

Gas supply lines 41A to 43A are installed in the hood 21 of the inner chamber 23. The gas supply lines 41A to 43A are opened toward the wafer W from the ceiling of the processing space 22 and supply gases into the processing space 22 downwardly. The gases supplied from the gas supply lines 41A to 43A press the wafer W against the stage 11. As a result, it is possible to keep the wafer W from rising over the stage 11 when gas is supplied so as to prevent a film forming process from being disrupted.

In addition, a relatively large pressure is exerted on the wafer W when the chain reaction of decomposition takes places, which will be described below. However, since the gas supply lines are installed as described above, nitrogen monoxide (NO) gas, which triggers the chain reaction of decomposition, is supplied from the top of the processing space 22, and accordingly, the chain reaction of decomposition takes place from the top to the bottom of the processing space 22. As a result, the wafer W is pressed against the stage 11, so that it is possible to effectively keep the wafer W from rising over the stage 11. In order to prevent a large pressure from being exerted on the wafer W locally during the chain reaction of decomposition, an end of a NO gas supply line 42A is opened above the center of the wafer W.

An end of each of the gas supply pipes 41 to 43 is connected to an upstream end of the respective gas supply lines 41A to 43A. The other end of each of the gas supply pipes 41 to 43 is led out of the outer chamber 25. The other end of the gas supply pipe 41 branches into two pipes to form a branched pipe; one of the two pipes is connected to an aminosilane gas supply source 51 via a valve V2, which is a source gas and the other of the two pipes is connected to a N₂ gas supply source 52 via a valve V3. The other end of the gas supply pipe 42 is connected to a NO gas supply source 53 which is an energy supply part via a valve V4. The other end of the gas supply pipe 43 branches into two pipes to form a branched pipe; one of the two pipes is connected to an ozone (O₃) gas supply source 54 via a valve V5, and the other of the two pipes is connected to a hydrogen (H₂) gas supply source 55 via a valve V6. The ozone (O₃) gas supply source 54 and the hydrogen (H₂) gas supply source 55 together work as an atmosphere gas supply part that creates a processing atmosphere for oxidizing the wafer W in the processing space 22.

Each of the gas supply sources 51 to 55 and 32, according to control signals output from a control part 10 to be described below, pumps out a gas toward the downstream end of the respective gas supply pipes and adjusts the flow rate of the gas. The aminosilane gas supplied from the gas supply source 51 working as a source gas supply part is a source for forming a film, and any gas may be used as long as it can be oxidized to form a silicon dioxide film. In this example, the gas supply source 51 supplies BTBAS (bis(tertiary-butylamino)silane) gas.

In addition, the O₃ gas supply source 54 may supply, for example, O₃ gas having an oxygen content of 8 vol % to 100 vol % into the processing space 22. In this exemplary embodiment of the present disclosure, the processing space 22 in which the wafer W is accommodated becomes ozone atmosphere, and NO gas, which is a reaction gas, is supplied into the processing space 22 containing hydrogen, such that ozone is decomposed. This will be described in more detail below. This decomposition is a forced chain reaction of decomposition, by which ozone is decomposed by NO to generate a reactive species such as an oxygen radical, and the reactive species decomposes nearby ozone to further generate a reactive oxygen species. That is, when NO gas is supplied into the processing space 22, the concentration of O₃ in the processing space 22 has to be high enough to trigger the chain reaction of decomposition. To form such an atmosphere in the processing space 22, O₃ gas is supplied from the O₃ gas supply source 54.

An exhaust line 17 is connected to the hood 21, facing the wafer W from the ceiling of the processing space 22. In addition, an end of an exhaust pipe 18 is installed in the hood 21 so as to be connected to the exhaust line 17. The other end of the exhaust pipe 18 is connected to the exhaust mechanism 35 via a flow rate controller 19. The flow rate controller 19 has the same configuration as that of the flow rate controller 34 and may adjust the flow rate of a gas from the processing space 22.

The film forming apparatus 1 includes the control part 10. The control part 10 may consist of, for example, a computer including a CPU and a memory. The control part 10 sends a control signal to each of the parts of the film forming apparatus 1, and controls operations including adjusting the opening/closing of the valves and the flow rates of the flow rate controllers 19 and 34, the amounts of gases supplied from the gas supply sources 51 to 55 and 32 to the gas supply pipes, ascending/descending the stage 11 by the elevation mechanism 13, etc. In order to output such control signals, a program that is a set of steps (instructions) is stored in the memory. The program is stored in a storage medium such as a hard disk, a compact disk, a magnet optical disk, a memory card, etc., and is installed in a computer therefrom.

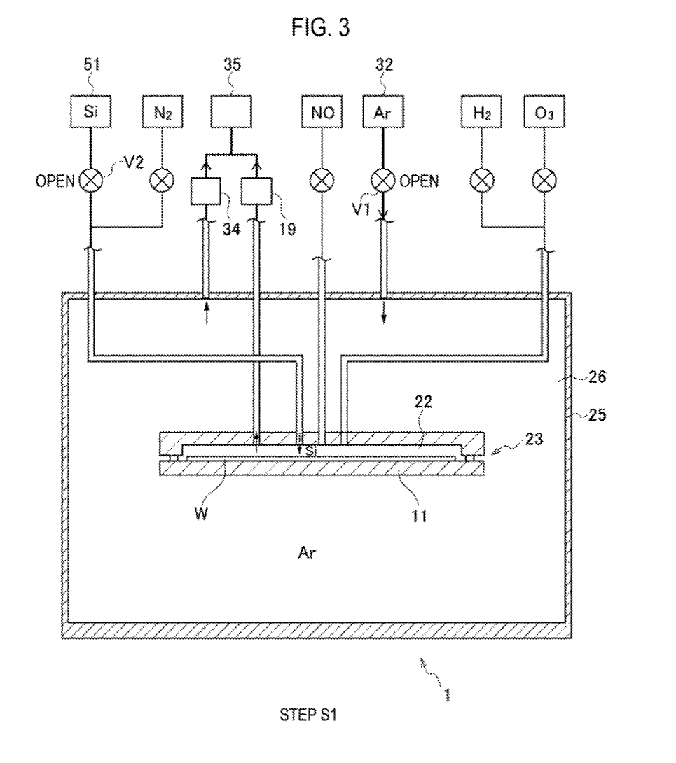

The operation of the film forming apparatus 1 will be described with reference to FIGS. 3 to 9. In FIGS. 3 to 9, gas flows into/out of the processing space 22 in the inner chamber 23 and the buffer area 26 in the outer chamber 25 are indicated by arrows. In addition, for easy understanding, the letter “OPEN” is denoted near a valve, wherever necessary, to indicate that the valve is open. The letter “OPEN” may be omitted in some places. In addition, a pipe through which a gas flows is indicated by a thicker line than a pipe through which a gas does not flow.

Initially, the stage 11 ascends from the position indicated by the dash-dot line in FIG. 1. Then, a wafer W supported by the supporting pins 28 is delivered to the stage 11 by the transfer mechanism. Then, the stage 11 ascends to the position indicated by the solid line in FIG. 1 and held at the position, such that the processing space 22 is defined by the stage 11 and the hood 21. The processing space 22 and the buffer area 26 are evacuated at certain flow rates adjusted by the flow rate controllers 19 and 34, respectively, and the valve V1 is opened such that Ar gas is supplied from the Ar gas supply source 32 into the buffer area 26.

While the processing space 22 and the buffer area 26 are evacuated and the Ar gas is supplied thereinto, the valve V2 is opened and aminosilane gas is supplied from the gas supply source 51 into the processing space 22. As a result, aminosilane molecules working as a source for forming a film are adsorbed onto the surface of the wafer W, such that a molecular layer of aminosilane is formed (Step S1 in FIG. 3). In the forming of the molecular layer, the pressure in the processing space 22 ranges, for example, from 1 Torr (0.13×10³ Pa) to 10 Torr (1.3×10³ Pa) so that the aminosilane gas is adsorbed onto the surface of the wafer W without creating particles. The pressure in the buffer area 26 is adjusted appropriately by the supplying of the Ar gas and the evacuation so that the processing space 22 is maintained at the above-mentioned ranges.

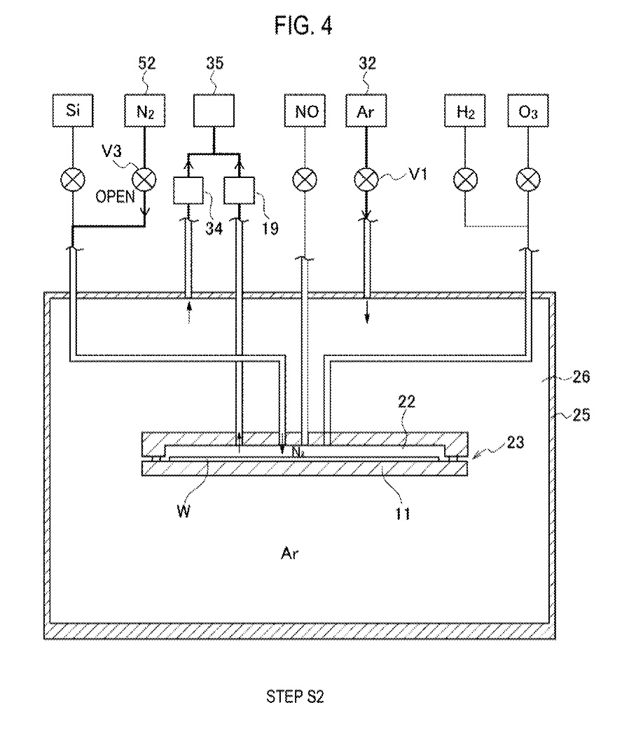

Subsequently, the valve V2 is closed, such that the supplying of the aminosilane gas into the processing space 22 is stop. Subsequently, the valve V3 is opened, such that N₂ gas is supplied from the N₂ gas supply source 52 into the processing space 22. Excessive aminosilane in the processing space 22, which is not adsorbed onto the wafer W, is purged out by the N₂ gas via the exhaust pipe 18 (Step S2 in FIG. 4).

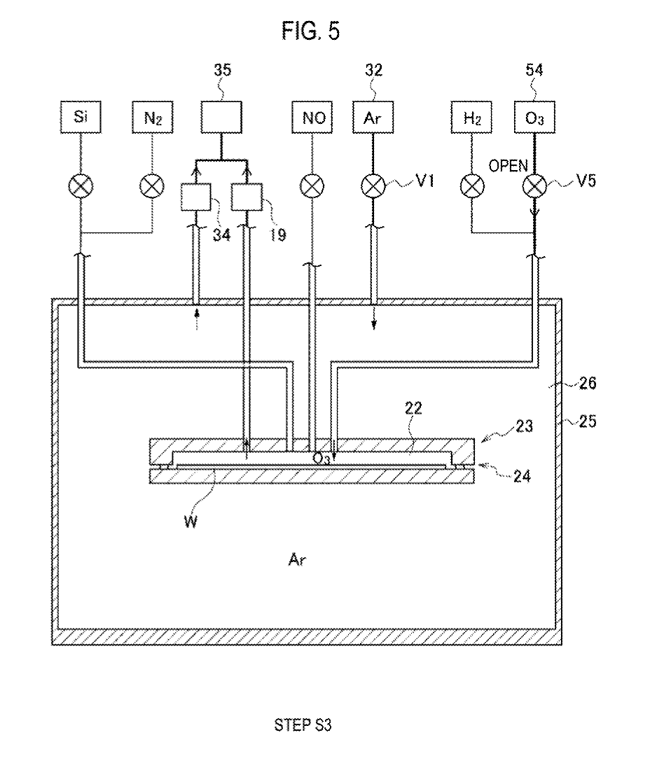

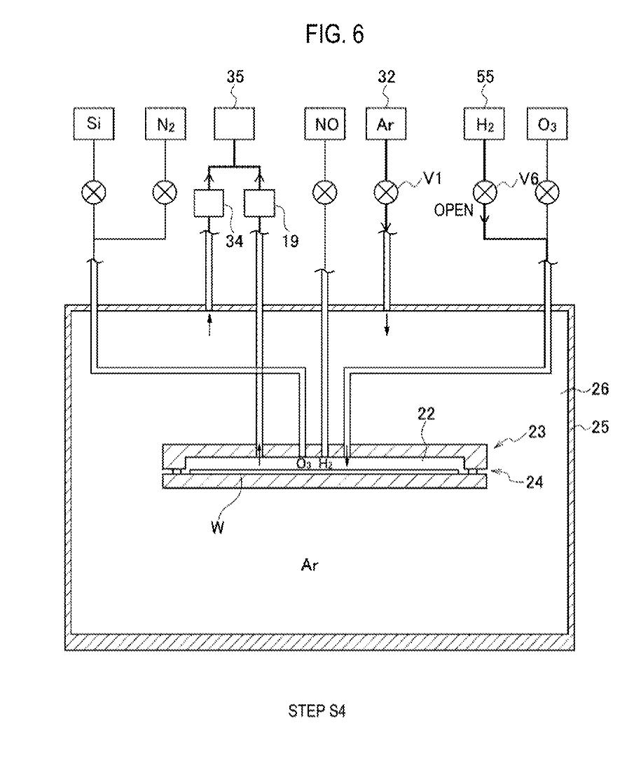

Subsequently, the valve V3 is closed such that the supplying of the N₂ gas into the processing space 22 is stop, and the valve V5 is opened such that O₃ gas is supplied into the processing space 22 from the O₃ gas supply source 54 (Step S3 in FIG. 5). As the O₃ gas is supplied into the processing space 22, the pressure in the processing space 22 becomes, for example, 50 Torr (6.5×10³ Pa). The pressure in the buffer area 26 also becomes, for example, 50 Torr, which is equal to that of the processing space 22, by the supply of the Ar gas and the evacuation. Subsequently, the valve V5 is closed such that the supplying of the O₃ gas into the processing space 22 is stopped, and the valve V6 is opened such that H₂ gas is supplied into the processing space 22 from the H₂ gas supply source 55 (Step S4 in FIG. 6).

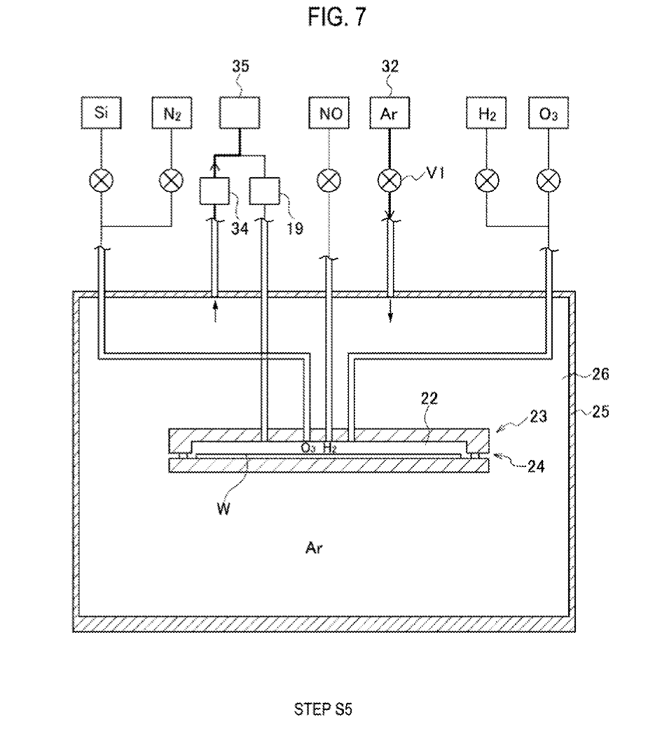

Subsequently, the valve V6 is closed such that the supplying of the H₂ gas into the processing space 22 is stopped, and the evacuation of the processing space 22 is stopped by the flow rate controller 19 (Step S5 in FIG. 7). At this time, the pressure in the processing space 22 remains at 50 Torr, which is equal to that of the buffer area 26. The concentration of ozone in the processing space 22 is high enough to trigger the above-mentioned chain reaction of decomposition when NO gas is supplied into the processing space 22 in the subsequent process.

Although the buffer area 26 is in communication with the processing space 22 via the gap 24 in the inner chamber 23 as described above, the Ar gas in the buffer area 26 is kept from flowing into the processing space 22, and the O₃ gas and the H₂ gas in the processing space 22 are kept from flowing into the buffer area 26, because the pressure in the buffer area 26 is equal to that in the processing space 22 as described above. That is, even though the gap 24 is formed, the O₃ gas and the H₂ gas are confined to the processing space 22, and the concentration of the O₃ gas in the processing space 22 is maintained high enough to trigger the chain reaction of decomposition.

Then, the valve V4 is opened such that NO gas is supplied into the processing space 22, and the NO gas comes in contact with ozone in the processing space 22. That is, the ozone ignites, such that the forced chain reaction of decomposition (a combustion reaction) of ozone occurs as previously described. As a result, reactive oxygen species are generated. The reactive oxygen species react with H₂ in the processing space 22, to generate a hydroxyl radical. The reactive oxygen species and the hydroxyl radical react with the molecular layer of aminosilane adsorbed on the surface of the wafer W, thereby oxidizing the aminosilane. As a result, a molecular layer of silicon dioxide is formed. This oxidation reaction will be described in more detail below.

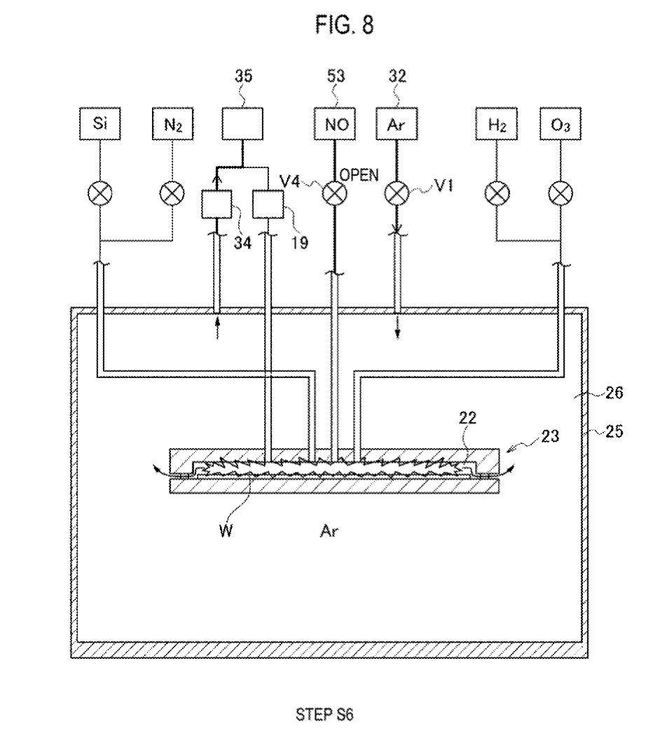

Since the forced chain reaction of decomposition of ozone occurs instantaneously, the amounts of the reactive oxygen species and the hydroxyl radical increases drastically in the processing space 22. That is, the gas is drastically expanded in the processing space 22. However, since the processing space 22 is in communication with the buffer area 26 as described above, the expanded gas flows into the buffer area 26. Thus, the pressure in the processing space 22 is prevented from increasing too much (Step S6 in FIG. 8).

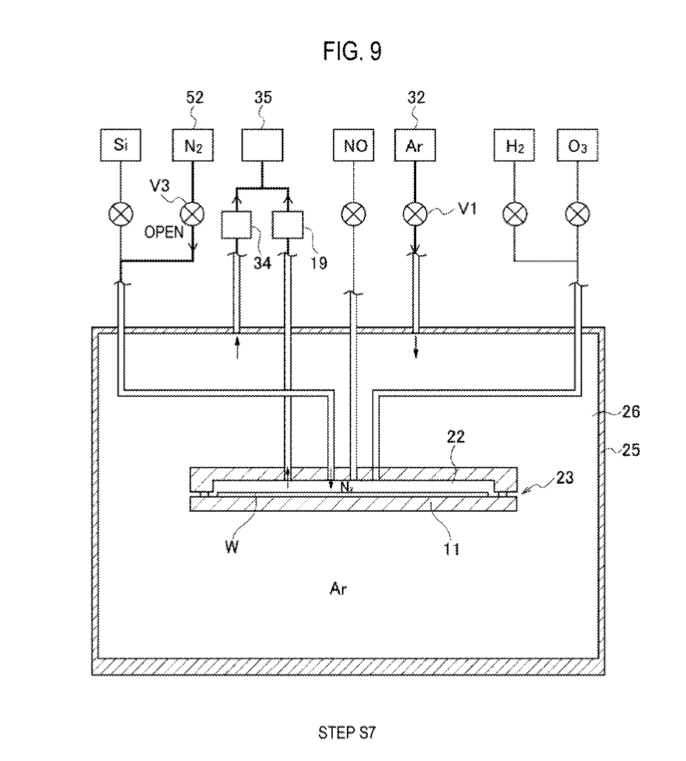

After the reactive oxygen species lose their reactivity and become oxygen, the hydroxyl radical also loses its reactivity, and the oxidization reaction ends. Subsequently, the evacuation of the processing space 22 is resumed by the flow rate controller 19, and the valve V3 is opened such that N₂ gas is supplied into the processing space 22. As a result, the oxygen and a compound produced as a hydroxyl radical loses its reactivity and are purged out of the processing space 22. In addition, as the Ar gas is supplied in the buffer area 26 and also the buffer area 26 is being evacuated, the oxygen produced as the reactive oxygen species lose their reactivity and the compound produced as the hydroxyl radical loses its reactivity, which flown from the processing space 22 into the buffer area 26 in Step S6, are purged out of the buffer area 26 (Step S7 in FIG. 9). Thereafter, the operations in Steps S1 to S7 are repeated. That is, the cycle is repeated a number of times where one cycle comprises of Steps S1 to S7. Further, a molecular layer of silicon dioxide is stacked on the wafer W per one cycle.

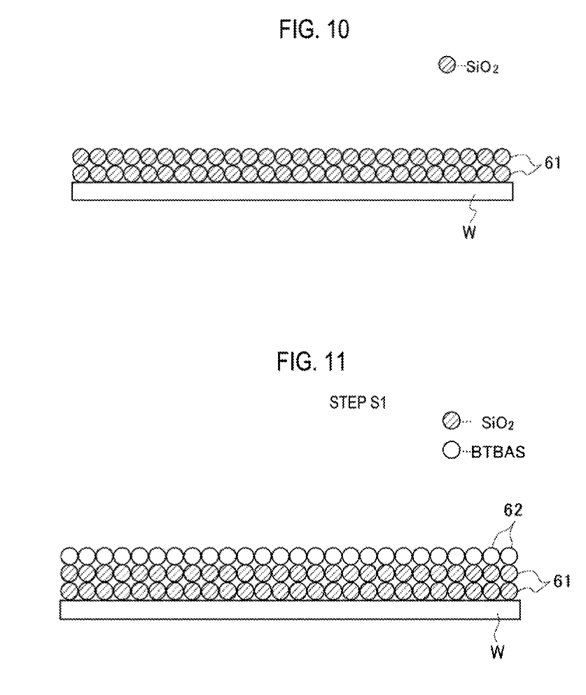

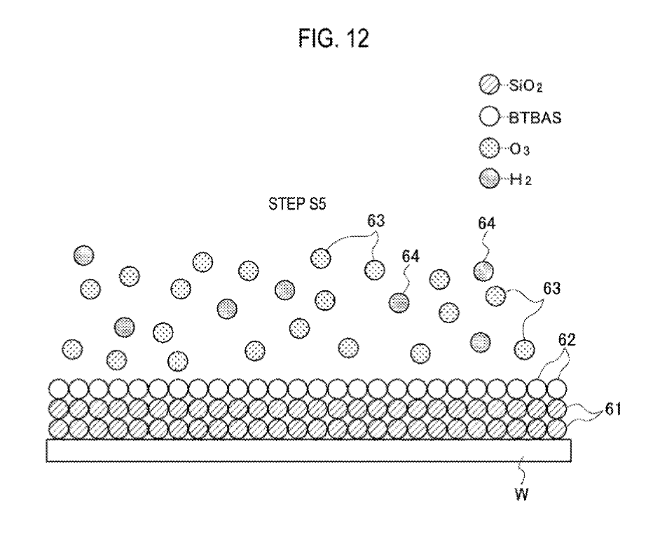

Changes in the conditions of the surface of the wafer W after the second or later cycle will be described with reference to FIGS. 10 to 16. FIG. 10 shows a surface of a wafer before a cycle is started. FIG. 11 shows that, after Step S1 of the cycle is performed, the aminosilane (BTBAS) molecule are adsorbed onto the surface of the wafer W such that a layer of aminosilane (BTBAS) molecule 62 is formed on the surface of the wafer W. As can be seen from the drawings, underlying layers 61 of silicon dioxide have already been formed on the surface of the wafer W under the layer of aminosilane molecule 62. In FIG. 12, O₃ gas and H₂ gas are confined to the processing space 22 at Step S5 of the cycle, where reference numbers 63 and 64 denote ozone and hydrogen molecules, respectively.

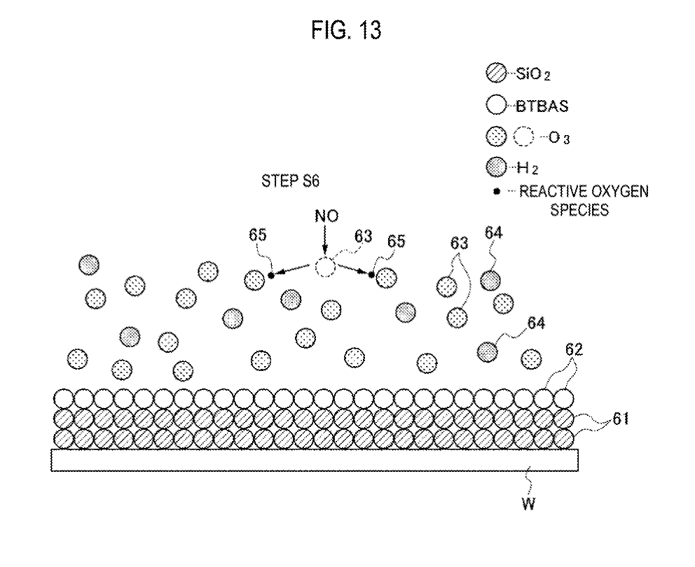

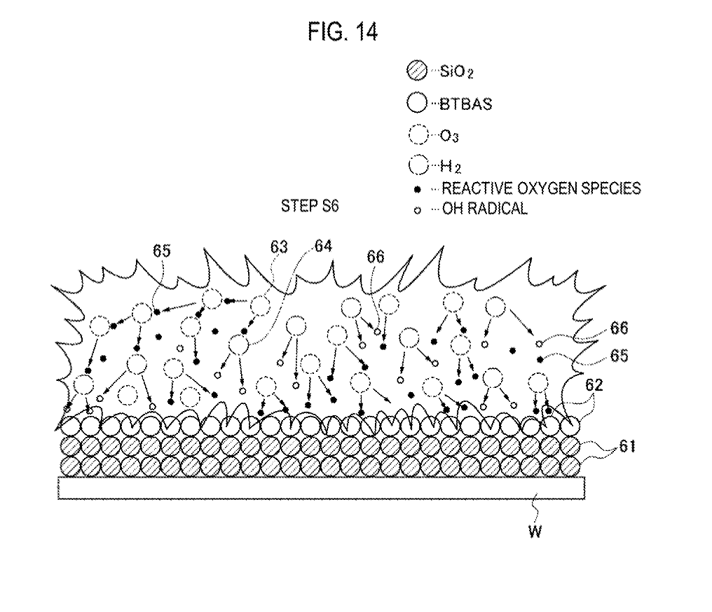

FIG. 13 shows the surface of the wafer when NO gas is supplied into the processing space 22 in the subsequent Step S6 of the cycle. As previously described, when NO reacts with ozone, energy is given to the ozone, and the ozone is forcibly decomposed to generate reactive oxygen species 65. Then, the ozone is forcibly decomposed by the reactive oxygen species 65, and the ozone is further decomposed by the produced reactive oxygen species. As such, chain decomposition of ozone takes place, such that the ozone in the processing space 22 instantaneously changes into the reactive oxygen species 65. In addition, during the process of the instantaneous chain reaction of decomposition, oxygen radical (O.), which is a kind of reactive oxygen species, reacts with hydrogen molecules 64 as expressed in Formula 1 below to produce hydroxyl radical 66 (see FIG. 14):

H₂+2O.→2OH. Formula 1

In addition, heat and light energy emitted from the chain reaction of decomposition is exerted to the aminosilane molecules 62 exposed to the space where the chain reaction of decomposition of the ozone takes place, and the energy of the aminosilane molecules 62 increases instantaneously and the temperature of the aminosilane molecules 62 increases. Since the reactive oxygen species 65 and the hydroxyl radical 66, both of which can react with the aminosilane molecules 62, exist in the vicinity of the aminosilane molecules 62 which became reactive as its temperature has been increased, the aminosilane molecules 62 react with the reactive oxygen species 65 and the hydroxyl radical 66. That is, the aminosilane molecules 62 are oxidized to become silicon dioxide molecules 61.

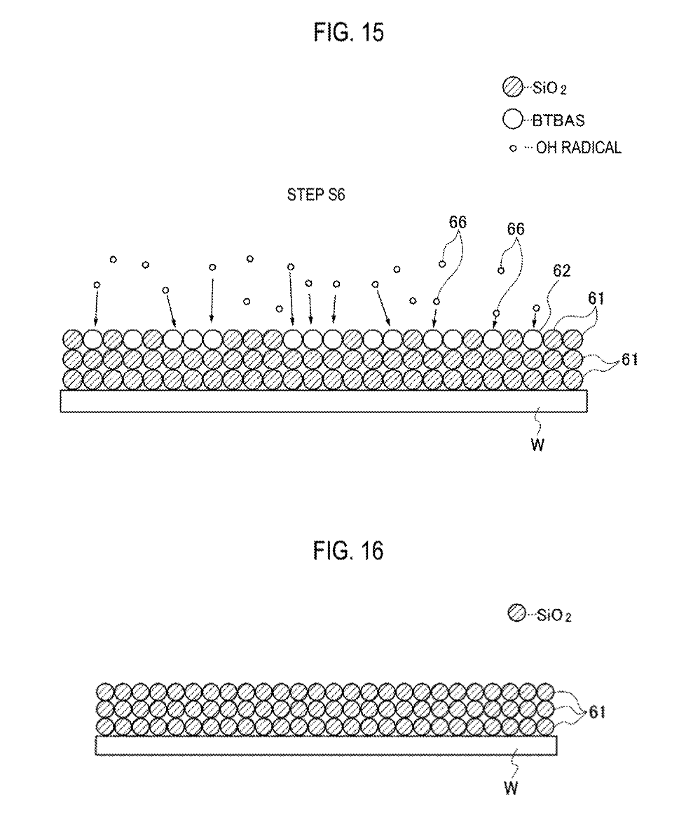

The reactive oxygen species 65 are unstable and thus lose their reactivity within several milliseconds from when they are created. However, the hydroxyl radical 66 has a lifetime of several hundreds of milliseconds which is longer than the lifetime of the reactive oxygen species 65. Accordingly, the aminosilane molecules 62 keep being oxidized by the hydroxyl radical 66 even after the reactive oxygen species 65 have lost their reactivity (FIG. 15). As a result, the oxidation of the aminosilane molecules 62 is more effectively carried out on the entire surface of the wafer W, thereby generating the silicon dioxide molecules 61 (FIG. 16).

Since the aminosilane molecules 62 receive the energy generated by the chain reaction of decomposition of ozone as described above, the aminosilane can be oxidized even without heating the wafer W by a heater as described in the Background. Although the process that the aminosilane molecules 62 are oxidized in Steps S1 to S7 of the second or later cycle has been described above, the same happens in Steps S1 to S7 of the first cycle as well. That is, the energy generated by the decomposition of ozone is exerted on the aminosilane molecules 62, and the aminosilane molecules 62 are oxidized by the reactive oxygen species 65 and the hydroxyl radical 66. When a silicon dioxide film having a desired thickness is formed after repeating the cycle a number of times, the stage 11 descends and the wafer W is passed to the supporting pins 28. Then, the wafer W is taken out of the outer chamber 25 by the transfer mechanism (not shown).

As described above, according to the film forming apparatus 1, the atmosphere containing ozone of a relatively high concentration and hydrogen is formed in the inner chamber 23, the ozone is decomposed by NO gas at the room temperature in a chain reaction, and the aminosilane on the surface of the wafer W is oxidized by the hydroxyl radical and the reactive oxygen species generated by the chain reaction of decomposition, thereby forming the silicon dioxide film. Since the hydroxyl radical has a longer lifetime than the reactive oxygen species, the aminosilane can be oxidized more effectively and a SiO₂ film having a desired film quality can be formed. In addition, the film forming apparatus 1 does not require any heating equipment such as a heater for heating a wafer W for oxidation, and thus the manufacturing and maintenance cost of the film forming apparatus 1 can be saved. In addition, the oxidation of the aminosilane can be carried out without waiting until the wafer W is heated up to a predetermined temperature by the heating equipment. Accordingly, the time required for the film forming process can be shortened, and the throughput can be improved. In addition, since the oxidation process is carried out sufficiently due to the hydroxyl radical, it is not necessary to trigger a chain reaction of decomposition repeatedly for oxidation in a cycle. As a result, the throughput can be further improved.

In addition, in the film forming apparatus 1, the processing space 22 in the inner chamber 23 is in communication with the buffer area 26 outside the inner chamber 23 via the gap 24. Accordingly, the gas drastically expanded in the processing space 22 by the chain reaction of decomposition is relieved to the buffer area 26, so that the increase in the pressure in the processing space 22 can be mitigated. As a result, damage to or deterioration of the wafer W due to the increase in the pressure can be suppressed. In addition to the wafer W, damage to or deterioration of the inner chamber 23 can be suppressed as well. In other words, the inner chamber 23 does not require high pressure-resistance, and thus may have a simple configuration. As a result, the manufacturing cost of the film forming apparatus 1 can be saved.

In the above processing example, in Step S5 before NO gas is supplied, the supply of gasses and the evacuation are controlled so that the pressure in the processing space 22 where O₃ gas and H₂ gas are supplied is equal to the pressure in the buffer area 26 where Ar gas is supplied, thereby a gas flow may not occur between the processing space 22 and the buffer area 26. In addition, in Step S6, the concentration of O₃ gas in the processing space 22 is maintained high enough to trigger the chain reaction of decomposition when NO gas is supplied. However, a gas flow may occur between the processing space 22 and the buffer area 26 as long as the concentration of ozone in the processing space 22 is maintained high enough to trigger the chain reaction of decomposition when the NO gas is supplied. That is, the pressure in the processing space 22 may differ from that of the buffer area 26 before the NO gas is supplied.

In the above processing example, the pressure in the processing space 22 is set to be 50 Torr in Step S5 in order to form an atmosphere where the chain reaction of decomposition is triggered. However, the pressure is not limited to the above value, the pressure in the processing space 22 may be lower than 50 Torr, e.g., 20 Torr (2.6×10³ Pa) to 30 Torr (3.9×10³ Pa) as long as the chain reaction of decomposition occurs. In Step S5, the higher the pressure in the processing space 22 is, the lower the required concentration of ozone in the processing space 22 and the buffer area 26 to trigger the chain reaction of decomposition becomes. However, the higher the pressure in the processing space 22 is in Step S5, the higher the pressure in processing space 22 and the pressure in the buffer area 26 at the time of the chain reaction of decomposition become. The pressure in the processing space 22 in Step S5 is set so that the atmosphere in the processing space 22 and the atmosphere in the buffer area 26 are maintained at a pressure lower than atmospheric pressure, i.e., vacuum pressure even at the time of the chain reaction of decomposition, thereby none of the inner chamber 23, the outer chamber 25 and the wafer W is damaged.

In the above processing example, the supply of Ar gas into the buffer area 26 and evacuation of the buffer area 26 are carried out in every step of a cycle. The supply of Ar gas and the evacuation have the purposes of confining O₃ gas and H₂ gas to the processing space 22, preventing an increase in the pressure in the processing space 22 during the chain reaction of decomposition, and purging out byproducts in the buffer area 26. Therefore, the supply of Ar gas and the evacuation of the buffer area 26 may not be carried out in Steps S1 and S2, for example.

When the chain reaction of decomposition takes place in Step S6, the supplied Ar gas may be confined to the buffer area 26, without supplying Ar gas into the buffer area 26 and evacuating the buffer area 26. In the above example, Ar gas is supplied into the buffer area 26 as an inert gas, and N₂ gas is supplied into processing space 22 as an inert gas. However, N₂ gas may be supplied into the buffer area 26, and Ar gas may be supplied into the processing space 22. Other inert gases other than Ar gas and N₂ gas may be used. In the above example, O₃ gas is supplied into the processing space 22 prior to H₂ gas being supplied. However, the sequence of supplying the gases may vary as long as both O₃ gas and H₂ gas are supplied into the processing space 22 before the chain reaction of decomposition takes place. Accordingly, O₃ gas may be supplied into the processing space 22 after H₂ gas is supplied, or a mixture gas of O₃ gas and H₂ gas may be supplied into the processing space 22.

### Second Embodiment

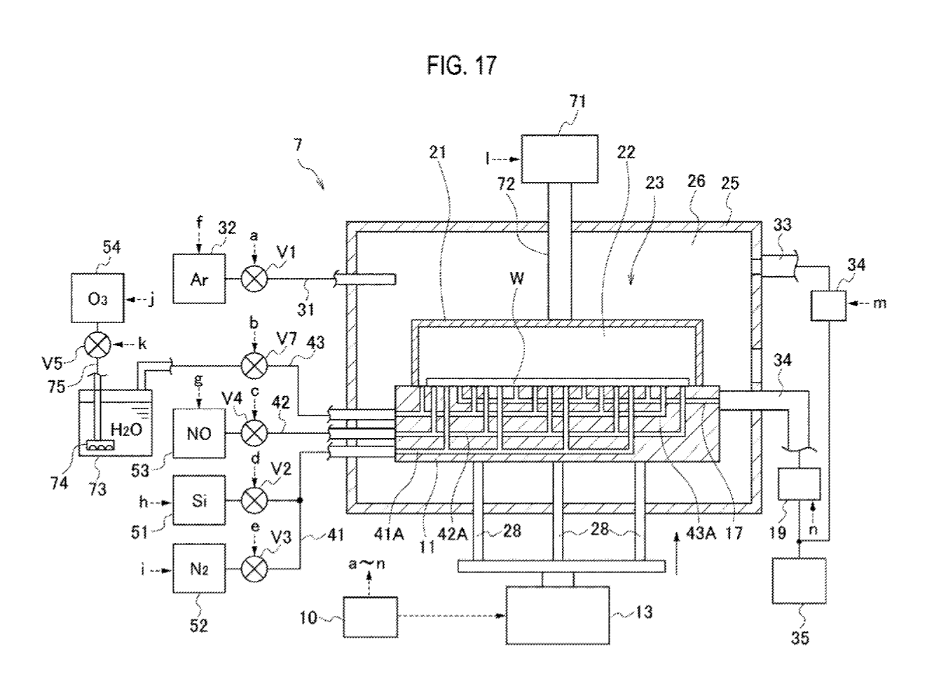

Hereinafter, a film forming apparatus 7 according to a second exemplary embodiment of the present disclosure will be described with reference to FIG. 17, focusing on the differences from the film forming apparatus 1. In the film forming apparatus 7, gas supply lines 41A to 43A and an exhaust line 17 are installed in a stage 11 instead of a hood 21, and an end of each of the gas supply lines 41A to 43A and the exhaust line 17 is opened at the surface of the stage 11 on which a wafer W is located. Accordingly, in the film forming apparatus 7, gas supply pipes 41 to 43 and an exhaust pipe 18 are connected to the stage 11 instead of the hood 21.

The stage 11 is fixed in a buffer area 26 by a supporting member (not shown). The hood 21 is connected to an elevation mechanism 71 installed outside an outer chamber 25 via a connecting member 72 and can ascend/descend with respect to the stage 11. Since the stage 11 has no spacing pins 15, the entire periphery of the lower portion of the hood 21 comes in contact with the surface of the stage 11 when the hood 21 descends, such that a processing space 22 is sealed. Accordingly, the elevation mechanism 71 works as a partitioning mechanism that separates the processing space 22 from the buffer area 26. FIG. 17 shows the sealed processing space 22. In addition, unlike the elevation mechanism 13 of the film forming apparatus 1, the elevation mechanism 71 of the film forming apparatus 7 raises/lowers the supporting pins 28 instead of stage 11. A wafer W is delivered between a transfer mechanism and the stage 11 by the supporting pins 28.

The upstream side of a gas supply pipe 43 is connected to a tank 73 via a valve V7. Liquid H₂O (water) is contained in the tank 73. The end of the gas supply pipe 43 is opened above the surface of the water contained in the tank 73. In addition, nozzles 74 for bubbling are installed below the surface of the water. The nozzles 74 are connected to the downstream end of a gas supply pipe 75. The upstream end of the gas supply pipe 75 is connected to an O₃ gas supply source 54 via a valve V5. In this film forming apparatus 7, water vapor produced from the evaporation of the liquid water in the tank 73 is supplied into the processing space 22, instead of H₂ gas used in the film forming apparatus 1. Specifically, the water in the tank 73 is bubbled with O₃ gas to evaporate into water vapor, and the water vapor is supplied into the processing space 22 along with the O₃ gas. That is, the O₃ gas works as a carrier gas for the water vapor.

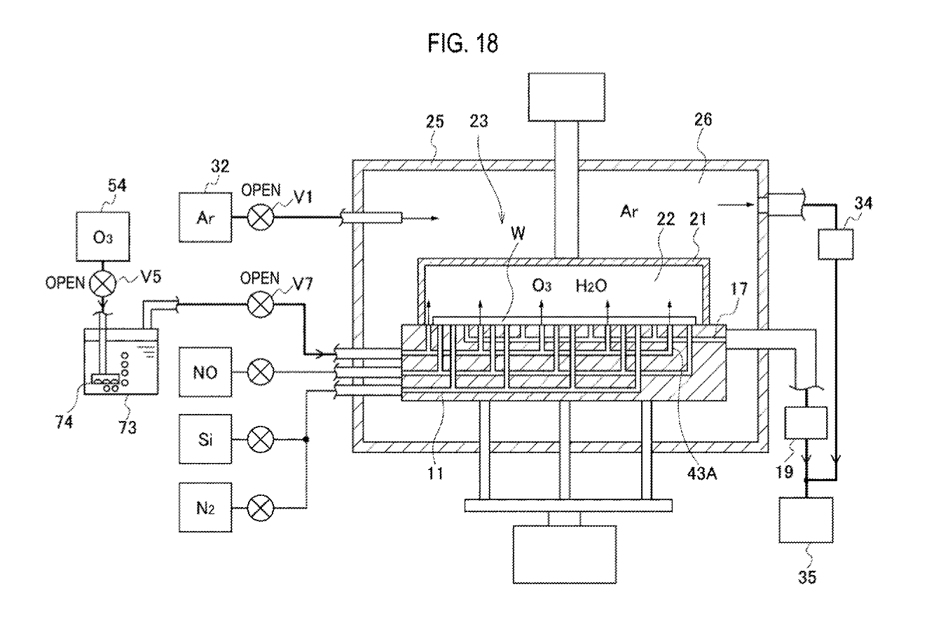

The film forming processes by the film forming apparatus 7 will be described focusing on the differences from the film forming apparatus 1 with reference to FIGS. 18 to 20 in which gas flows are indicated by arrows. Like the film forming apparatus 1, the film forming processes by the film forming apparatus 7 are also carried out according to control signals sent to each part from a control part 10. Initially, when the hood 21 ascends to a position higher than the position shown in FIG. 17, a wafer W is delivered from a transfer mechanism to the stage 11. Then, the hood 21 descends to seal the processing space 22.

Subsequently, like in Step S1 performed by the film forming apparatus 1, Ar gas is supplied into the buffer area 26 and the buffer area 26 is evacuated, such that the pressure in the buffer area 26 becomes, e.g., 50 Torr. Meanwhile, aminosilane gas is supplied into the processing space 22 and the processing space 22 is evacuated, such that aminosilane is adsorbed onto the wafer W. Subsequently, like in Step S2 performed by the film forming apparatus 1, the processing space 22 is evacuated and N₂ gas is supplied into the processing space 22. Excessive aminosilane gas is purged out.

Subsequently, valves V5 and V7 are opened with the processing space 22 evacuated such that O₃ gas is supplied into the tank 73 to perform bubbling and a mixture gas of ozone gas and water vapor is supplied into the processing space 22 (see FIG. 18). As a result, the concentration of ozone in the processin space 22 increases high enough to trigger the above-described chain reaction of decomposition. In addition, the pressure in the processing space 22 becomes 50 Torr, for example, which is equal to the pressure in the buffer area 26. That is, the operations corresponding to those in Steps S3 and S4 performed by the film forming apparatus 1 are carried out.

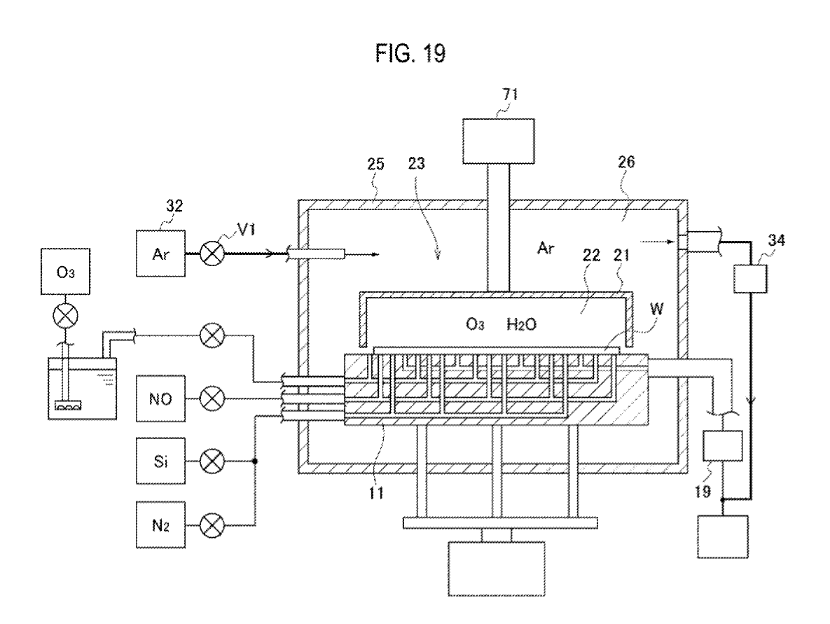

Subsequently, valves V5 and V7 are closed such that the bubbling is completed, and the supply of the mixture gas into the processing space 22 is stop. In addition, as the supply of the mixture gas is stopped, the evacuation of the processing space 22 is stopped by a flow rate controller 19. Subsequently, the hood 21 slightly ascends, such that the processing space 22 is in communication with the buffer area 26 via a gap formed between the lower portion of the hood 21 and the surface of the stage 11 (see FIG. 19). Like in Step S5 performed by the film forming apparatus 1, the gas flow between the buffer area 26 and the processing space 22 is suppressed because the pressure in the buffer area 26 is equal to the pressure in the processing space 22.

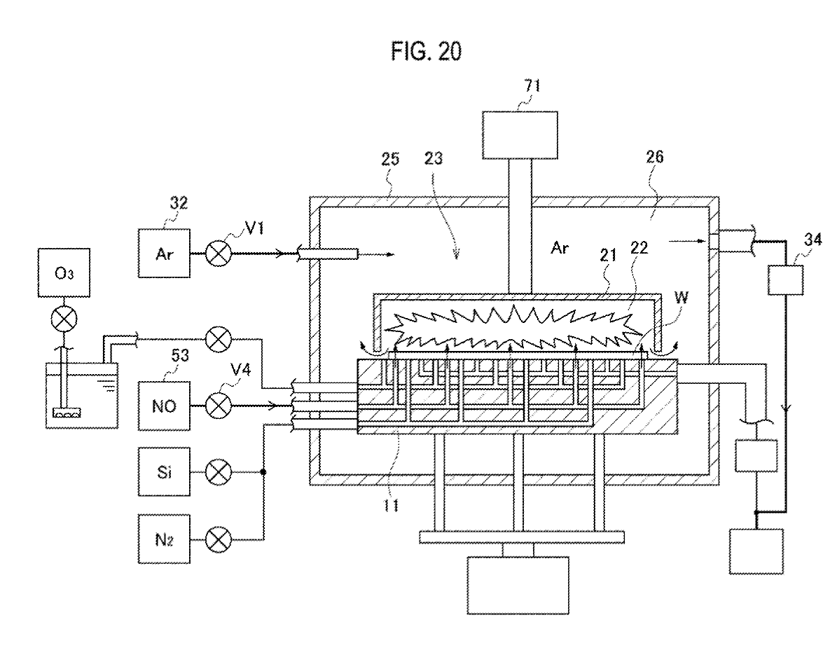

Subsequently, like in Step S6 performed by the film forming apparatus 1, NO gas is supplied into the processing space 22, and a chain reaction of decomposition occurs, such that reactive oxygen species are generated. The reactive oxygen species react with water, such that hydroxyl radical is generated. Like the film forming apparatus 1, the aminosilane adsorbed onto the wafer W is oxidized by the hydroxyl radical and the reactive oxygen species (see FIG. 20). Since the gas in the processing space 22 may flow into the buffer area 26 via the gap between the lower portion of the hood 21 and the surface of the stage 11, an increase in the pressure in the processing space 22 by the chain reaction of decomposition is suppressed, like the film forming apparatus 1. After the chain reaction of decomposition, like in Step S7, the processing space 22 is evacuated and N₂ gas is supplied into the processing space, such that the byproducts in the processing space 22 is purged out. A cycle including the operations corresponding to those in Steps S1 to S7 performed by the film forming apparatus 1 is repeated, such that a SiO₂ film is formed on the surface of the wafer W.

Like the film forming apparatus 1, aminosilane is oxidized with the hydroxyl radical in the film forming apparatus 7 as well. Accordingly, oxidation is carried out in a longer period of time, compared to oxidation only with reactive oxygen species. As a result, like the film forming apparatus 1, the oxidation can be carried out more effectively. In addition, it is not necessary to carry out a chain reaction of decomposition several times in a cycle. In the film forming apparatus 7, water is used to produce the hydroxyl radical. The water reacts with the oxygen radical as expressed in Formula 2 below:

H₂O+O.→2OH. Formula 2

In Formula 1 described above with respect to the film forming apparatus 1, two oxygen radicals are used for producing two hydroxyl radicals from one hydrogen molecule. In contrast, as can be seen from Formula 2, only one oxygen radical is used for producing two hydroxyl radicals from one water molecule. That is, less oxygen radicals are used with H₂O than H₂ for producing a hydroxyl radical. Accordingly, it is possible to increase the concentration of the hydroxyl radical with H₂O, and thus aminosilane can be oxidized more effectively.

In the film forming apparatus 7, it is possible to separate the buffer area 26 from the processing space 22 immediately before NO gas is supplied, and thus gas flow between the buffer area 26 and the processing space 22 can be effectively suppressed, triggering the chain reaction of decomposition more effectively. In the above configuration example, the hood 21 rises/lowers relative to the stage 11. However, the stage 11 may rise/lower relative to the hood 21, such that the buffer area 26 is separated from/in communications with the processing space 22.

In this regard, as the gas supplied into the processing space 22 along with the ozone gas, any hydrogen donor may be used as long as it can donate hydrogen to the reactive oxygen species generated by the chain reaction of decomposition to generate the hydroxyl radical. As the hydrogen donor, for example, hydrogen peroxide (H₂O₂) may be used, in addition to the above-mentioned water and hydrogen. The hydrogen donor reacts with the reactive oxygen species to generate hydroxyl radical as expressed in Formula 3 below:

H₂O₂+O.→2OH.+O. Formula 3

In the film forming apparatuses 1 and 7, for example, it is also possible to supply NO gas into the processing space 22 where ammonia gas, methane gas, diborane gas, etc. is supplied in advance, along with O₃ gas and hydrogen donor. These gases are decomposed when O₃ is decomposed, and chemically react with aminosilane, thereby forming a silicon dioxide film in which the elements of the gases are doped. Specifically, ammonia gas, methane gas and diborane gas are supplied into the processing space 22 to form a silicon dioxide film in which nitrogen (N), carbon (C) and boron (B) are doped. In order to carry out such a doping in the exemplary embodiments of the present disclosure, the gases for doping are supplied into the processing space 22 after the byproducts in the processing space 22 are purged out immediately after the aminosilane is adsorbed, and until NO gas is supplied into the processing space 22. The gases for doping may be supplied via the above-described gas supply lines 41A to 43A.

The source gas used in the above exemplary embodiments of the present disclosure is not limited to that for forming the silicon dioxide film as described above. For example, trimethylaluminum (TMA), Tetrakis(ethylmethylamino)hafnium (TEMHF), bis(tetra methyl heptandionate) strontium (Sr(THD)₂), (methyl-pentadionate) (bis-tetra-methyl-heptandionate) titanium (Ti(MPD)(THD)), etc may be used, to form a film of aluminum oxide, hafnium oxide, strontium oxide, titanium oxide, etc, respectively.

The technologies in the above exemplary embodiments of the present disclosure may be combined. Specifically, in the film forming apparatus 1, a gas containing hydrogen may be supplied by bubbling as described with respect to the second exemplary embodiment. In addition, in the second exemplary embodiment, hydrogen gas may be supplied into the processing space 22. In addition, the film forming apparatuses according to the exemplary embodiments of the present disclosure are not limited to being used as the apparatuses performing oxidation in an ALD process, but may be used as standalone apparatuses performing oxidation. In addition, the way of decomposing O₃ gas is not limited to giving energy to the O₃ gas by the chemical reaction between the NO gas and the O₃ gas. The decomposition may be carried out by installing an electrode in the inner chamber 23 to cause discharge or by installing a laser mechanism in the inner chamber 23 to irradiate a laser beam into the processing space 22 to give energy to O₃ gas.

<Evaluation Tests>

Tests conducted for evaluating effects of the exemplary embodiments of the present disclosure will be described. In Evaluation Test 1, as described above with respect to the exemplary embodiments of the present disclosure, ozone gas of a concentration high enough to trigger the chain reaction of decomposition was confined to the processing space 22 together with H₂ gas. Then, NO gas was supplied into the processing space 22 to trigger the chain reaction of decomposition, thereby generating an OH radical. The flow rate of H₂ gas was changed whenever the process was conducted.

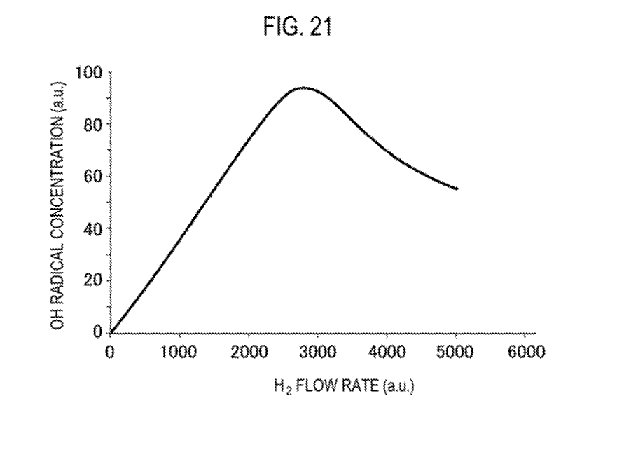

FIG. 21 is a graph showing a result of Evaluation Test 1. The horizontal axis of the graph represents the flow rate of H₂ gas. The vertical axis of the graph represents concentration of OH radical. The flow rate and the concentration increase with their numerical values. The numerical values are expressed in arbitrary units. The concentration of OH radical on the vertical axis of the graph represents a ratio of the amount of OH radical with respect to the amount of total elements in the processing space 22 at the time of decomposition reaction. As can be seen from the graph, the concentration of the OH radical increases as the flow rate of H₂ increases until the flow rate of H₂ reaches a certain value. The concentration of the OH radical decreases as the flow rate of H₂ increases after the flow rate of H₂ has passed the certain value.

This result could be explained by the following reason: there are a great amount of reactive oxygen species relative to H₂ gas when the decomposition reaction takes place until the flow rate of H₂ gas reaches the certain flow rate. However, as the flow rate of H₂ exceeds the certain value, the amount of reactive oxygen species becomes smaller than the amount of H₂ gas when the decomposition reaction takes place, and the amount of the OH radical has peaked out, such that amount of H₂ gas that did not participate in reaction increases. Therefore, it can be seen from this test that it is necessary to appropriately set the ratio of the amount of hydrogen gas with respect to the amount of ozone in the processing space 22 for controlling the concentration of the OH radical in order to perform oxidation reaction properly.

Next, Evaluation Test 2 for evaluating the thermal history of a silicon dioxide film formed by performing the processes according to the exemplary embodiments of the present disclosure will be described. In Evaluation Test 2, phosphorus (P) was implanted into a plurality of substrates made of silicon by ion implantation. The ion implantation was carried out with the energy of 2 keV and the dose of 1E15 ions/cm². Subsequently, a silicon dioxide film was formed on the P-implanted substrates, using the film forming apparatus 1.

The silicon dioxide film was formed by repeating the cycle one hundred times. It is to be noted that hydrogen was not supplied in Evaluation Test 2. That is, the oxidation was performed only with reactive oxygen species, irrespective of the hydroxyl radical. In Step S3 of each of the cycles, O₃ gas was supplied so that the ozone concentration in the inner chamber 23 became 77.7 vol %. Then, a silicon dioxide film was formed. The resistance value of the silicon dioxide film was measured. Some of the P-implanted substrates with no silicon dioxide film formed thereon were heated at different temperatures for 5 minutes to be used as references. After the heating, the resistance values of the references were measured.

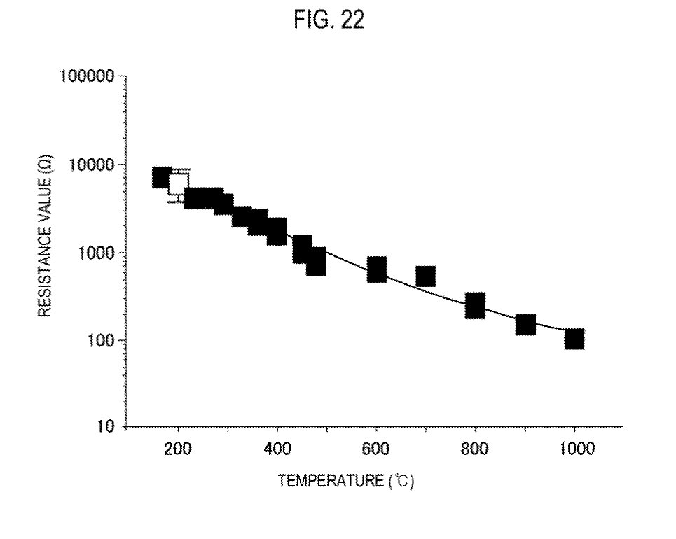

FIG. 22 is a graph showing a result of Evaluation Test 2. The plot with black boxes represents resistance values of references, while the plot with the white box represents a resistance value of the silicon dioxide film formed by the film forming apparatus 1. As can be seen from the graph, the resistance value of the silicon dioxide film is equal to that of the reference heated at the temperature of 200 degrees C. That is, the repeating of the cycle one hundred times according to the exemplary embodiments of the present disclosure achieves the resistance value obtained when a substrate is heated at 200 degrees C. for five minutes. That is, it could be concluded that the substrate is heated by the chain decomposition reactions, and the aminosilane can be oxidized by the heat without using a heater to heat the substrate, as previously mentioned.

Even though the temperature in the processing space 22 increases to approximately 1,700 degrees C. at the time of forced chain reaction of decomposition, the temperature of the substrate is restricted to 300 degrees C. or below. The temperature of the substrate would not substantially deviate from 300 degrees C. at the time of forced chain reaction of decomposition even when a hydrogen donor is added to generate a hydroxyl radical. Accordingly, it can be said that the exemplary embodiments of the present disclosure are especially effective for processing a wafer W when it is required to keep the temperature of the wafer W below 350 degrees C., as discussed in the BACKGROUND section of this disclosure.

According to the present disclosure in some embodiments, it is possible to form a gas atmosphere containing ozone of a concentration high enough to trigger forced decomposition reaction (chain reaction of decomposition) to generate a reactive oxygen species, and hydrogen donor in a vacuum chamber. In this atmosphere, the decomposition reaction occurs, and a source on a surface of a substrate receives a relatively large energy by the decomposition reaction and is oxidized by a reactive oxygen species and hydroxyl radical produced from the reaction of the hydrogen donor. Since the hydroxyl radical stays longer than the reactive oxygen species in terms of the time from their generation to loss of their reactivity, it can oxidize the surface of the substrate more effectively. Accordingly, it is possible to perform oxidation sufficiently even without heating the substrate with heating equipment such as a heater.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus for oxidizing a surface of a substrate in a vacuum atmosphere formed within a vacuum chamber, the apparatus comprising:
an atmosphere gas supply part configured to supply an atmosphere gas into the vacuum chamber to form a processing atmosphere containing an ozone and a hydrogen donor, wherein a concentration of the ozone is above a threshold concentration to trigger chain reaction of decomposition; and
an energy supply part configured to supply an energy to the processing atmosphere to oxidize the surface of the substrate with reactive species generated by forcibly decomposing the ozone and a hydroxyl radical generated by reaction of the hydrogen donor.

2. The substrate processing apparatus of claim 1, further comprising a buffer area in communication with the vacuum chamber at least when the energy is supplied, so as to mitigate an increase in a pressure in the vacuum chamber caused by the decomposition of the ozone when an inert gas is supplied.

3. The substrate processing apparatus of claim 2, wherein the buffer area is defined by an inner space of an outer chamber surrounding the vacuum chamber, and
wherein a gas flow channel is formed in the vacuum chamber to communicate the buffer area with the vacuum chamber.

4. The substrate processing apparatus of claim 3, wherein the vacuum chamber comprises a stage on which the substrate is loaded and a hood covering the stage, and
wherein the gas flow channel is a gap formed between the stage and the hood.

5. The substrate processing apparatus of claim 4, further comprising a partitioning part configured to close the gap when the atmosphere gas is supplied into the vacuum chamber so as to separate the vacuum chamber from the buffer area, and open the gap when the energy is supplied so as to make the vacuum chamber in communication with the buffer area.

6. The substrate processing apparatus of claim 1, wherein the atmosphere gas supply part comprises:
a tank in which the hydrogen donor in a liquid phase is contained;
an ozone gas supply part configured to perform bubbling by supplying an ozone gas below a surface of the hydrogen donor to evaporate the hydrogen donor; and
a gas supply line configured to supply the evaporated hydrogen donor into the vacuum chamber using the ozone gas as a carrier gas.

7. The substrate processing apparatus of claim 1, wherein the hydrogen donor is one of hydrogen, water and hydrogen peroxide.

8. The substrate processing apparatus of claim 1, wherein the energy supply part comprises a reaction gas supply part configured to supply a reaction gas into the processing atmosphere such that the reaction gas reacts with the ozone to trigger the forced decomposition reaction.

9. The substrate processing apparatus of claim 8, wherein the reaction gas is nitrogen monoxide.

10. The substrate processing apparatus of claim 8, wherein the vacuum chamber comprises a supply hole for supplying the reaction gas into the vacuum atmosphere, and
wherein the supply hole is opened toward a center of the substrate loaded into the vacuum chamber.

11. The substrate processing apparatus of claim 1, wherein the substrate processing apparatus is configured as a film forming apparatus comprising:
a source gas supply part configured to supply a source gas containing a source toward the substrate so that the source is adsorbed onto the substrate within the vacuum chamber; and
a control part configured to output control signals such that a cycle comprising the supply of the source gas, the formation of the processing atmosphere and the supply of energy carried out in this order is repeated for more than one time, to form a molecular layer of oxide on the surface of the substrate.

12. A substrate processing method of oxidizing a surface of a substrate in a vacuum atmosphere formed within a vacuum chamber, the method comprising:
supplying an atmosphere gas into the vacuum chamber to form a processing atmosphere containing an ozone and a hydrogen donor, wherein a concentration of the ozone is above a threshold concentration to trigger chain reaction of decomposition; and
supplying an energy to the processing atmosphere to oxide the surface of the substrate with reactive species generated by forcibly decomposing the ozone and hydroxyl radical generated by reaction of the hydrogen donor.

13. The substrate processing method of claim 12, wherein supplying an atmosphere gas comprises:
performing bubbling by supplying an ozone gas below a surface of the hydrogen donor in a liquid phase contained in a tank to evaporate the hydrogen donor; and
supplying the evaporated hydrogen donor into the vacuum chamber through a gas supply line using the ozone gas as a carrier gas.

14. The substrate processing method of claim 12, wherein supplying an energy comprises supplying a reaction gas into the processing atmosphere such that the reaction gas reacts with the ozone to trigger the forced decomposition reaction.

15. The substrate processing method of claim 14, wherein the reaction gas is nitrogen monoxide.

16. The substrate processing method of claim 14, wherein supplying a reaction gas into the processing atmosphere comprises supplying the reaction gas into the processing atmosphere from a supply hole formed in the vacuum chamber, the supply hole opened toward a center of the substrate loaded into the vacuum chamber.

17. The substrate processing method of claim 12, comprising:
supplying a source gas containing a source toward the substrate so that the source is adsorbed on the substrate within the vacuum chamber; and
repeating a cycle comprising supplying a source gas, supplying an atmosphere gas and supplying an energy carried out in this order for more than one time, to form a molecular layer of oxide on the surface of the substrate.

18. A non-transitory computer-readable storage medium having a computer program thereon, wherein the computer program, when executed in a substrate processing apparatus of oxidizing a surface of a substrate in a vacuum atmosphere formed within a vacuum chamber, causes the apparatus to perform the substrate processing method of claim 12.
